(19) United States
(12) Patent Application Publication
(10) Pub. No.: US 2023/0393249 A1
(43) Pub. Date: Dec. 7, 2023

(54) SENSOR DEVICE AND SENSING MODULE

(71) Applicant: SONY SEMICONDUCTOR SOLUTIONS CORPORATION, Kanagawa (JP)

(72) Inventors: Kyohei MIZUTA, Kanagawa (JP); Hajime YAMAGISHI, Kanagawa (JP)

(73) Assignee: SONY SEMICONDUCTOR SOLUTIONS CORPORATION, Kanagawa (JP)

(21) Appl. No.: 18/249,098

(22) PCT Filed: Oct. 7, 2021
(86) PCT No.: PCT/JP2021/037144

§ 371 Date: Apr. 14, 2023

(30) Foreign Application Priority Data
Oct. 22, 2020 (JP) 2020-177346

(51) Int. Cl. G01S 7/4915; G01S 7/481; G01S 17/32

(52) U.S. Cl. CPC G01S 7/4915; G01S 7/4816; G01S 17/32

(57) ABSTRACT

A sensor device according to the present technology includes: a semiconductor substrate; and a wiring layer part formed on the semiconductor substrate and having a plurality of wiring layers, in which a pixel is disposed in a laminated structure of the semiconductor substrate and the wiring layer part, the pixel including a photoelectric conversion element that performs photoelectric conversion, a first charge holding part and a second charge holding part that hold charges accumulated in the photoelectric conversion element, a first transfer transistor that transfers the charges to the first charge holding part, and a second transfer transistor that transfers the charges to the second charge holding part, and a shield part is disposed to surround each gate wiring line of each of the first and second transfer transistors extending in a thickness direction in the wiring layer part.

### TECHNICAL FIELD

The present technology relates to a sensor device including a pixel that transfers charges accumulated in a photoelectric conversion element to different charge holding parts by two transfer transistors, and a sensing module, and particularly relates to a technical field related to reduction of power consumption.

### BACKGROUND ART

As a distance measurement technique, a technique of performing distance measurement using a time of flight (ToF) method has been proposed. As the ToF method, there are a direct ToF method and an indirect ToF method.

In the indirect ToF method, light emitted from a light source is reflected by an object, and the reflected light from the object is photoelectrically converted by a photoelectric conversion element such as a photodiode. Then, signal charges obtained by the photoelectric conversion are distributed to two floating diffusions (FDs) by a pair of transfer transistors that are alternately driven.

Note that Patent Document 1 below discloses a technology of a distance measuring module that performs distance measurement by the indirect ToF method.

### CITATION LIST

### Patent Document

Patent Document 1: Japanese Patent Application Laid-Open No. 2020-13909

### SUMMARY OF THE INVENTION

### Problems to be Solved by the Invention

Here, in the indirect ToF method, because the pair of transfer transistors described above is driven at high speed to repeat on/off in a short cycle of, for example, 10 megahertz (MHz) to 200 MHz, there is a problem that the power consumption increases.

The present technology has been made in view of the circumstances described above, and an object thereof is to reduce the power consumption of a sensor device configured to transfer charges accumulated in a photoelectric conversion element to separate charge holding parts by two transfer transistors, such as in the indirect ToF type sensor device.

### Solutions to Problems

A sensor device according to the present technology includes: a semiconductor substrate; and a wiring layer part disposed on the semiconductor substrate and having a plurality of wiring layers, in which: the semiconductor substrate and the wiring layer part constitute a laminated structure in which a pixel is disposed, the pixel including a photoelectric conversion element that performs photoelectric conversion, a first charge holding part and a second charge holding part that hold charges accumulated in the photoelectric conversion element, a first transfer transistor that transfers the charges to the first charge holding part, and a second transfer transistor that transfers the charges to the second charge holding part; and a shield part surrounding a gate wiring line is formed for the gate wiring line of each of the first transfer transistor and the second transfer transistor extending in a thickness direction in the wiring layer part.

The shield part can reduce the capacitive load on the gate wiring line from the peripheral wiring lines.

The sensor device according to the present technology described above is conceivable to have a configuration in which the shield part is disposed across a plurality of the wiring layers.

With this arrangement, a range in which the shield part covers the gate wiring line in the laminating direction of the wiring layer part becomes wider.

The sensor device according to the present technology described above is conceivable to have a configuration in which the gate wiring line includes a wiring line extending in an in-plane direction on the inner side of the shield part.

With this arrangement, at the time of forming the gate wiring line in the region on the inner side of the shield part, the same process as the forming process of the wiring line in the outer region of the shield part can be applied, the process including the forming of the wiring line (to be dummy) in each wiring layer part before the forming of a via for one layer.

The sensor device according to the present technology described above is conceivable to have a configuration in which the gate wiring line includes a through via penetrating the plurality of the wiring layers.

By forming the through via, the wiring line does not need to be formed in the in-plane direction in the gate wiring line, which enables the gate wiring line to be made thin.

The sensor device according to the present technology described above is conceivable to have a configuration in which the wiring layer part includes an inter-pixel wiring line being a connection destination of the gate wiring line in a farthest wiring layer which is the wiring layer farthest from the semiconductor substrate among the wiring layer part, and the shield part extends from an adjacent wiring layer of the farthest wiring layer in the wiring layer part toward a side of the semiconductor substrate.

With this arrangement, in a case where the shield part is formed by digging the trench into the wiring layer part, the range in which the shield part covers the gate wiring line in the laminating direction of the wiring layer part can be maximized.

The sensor device according to the present technology described above is conceivable to have a configuration in which the shield part has an annular cross-sectional shape in the in-plane direction.

With this arrangement, in a case where the shield part is formed by digging the trench into the wiring layer part, the depth of the shield part can be easily made uniform.

The sensor device according to the present technology described above is conceivable to have a configuration in which the shield part includes an insulating material that is different from an interlayer insulating material in the wiring layer part.

With this arrangement, the shield part can include a material having higher insulating properties than the interlayer insulating material.

The sensor device according to the present technology described above is conceivable to have a configuration in which the shield part includes a Low-k material.

With this arrangement, the insulating properties of the shield part is enhanced.

The sensor device according to the present technology described above is conceivable to have a configuration in which the shield part includes a cavity part.

With this arrangement, in a case where the shield part is formed by digging the trench into the wiring layer part, a process of filling the trench with the insulating material becomes unnecessary.

The sensor device according to the present technology described above is conceivable to include a sensor device for distance measurement using the indirect ToF method.

In the indirect ToF, because the first and second transfer transistors are driven at high speed, the power consumption tends to increase.

A sensing module according to the present technology includes: a light-emitting unit that emits light for distance measurement; and a sensor unit that receives the light emitted from the light-emitting unit and reflected by an object, in which: the sensor unit includes a semiconductor substrate and a wiring layer part disposed on the semiconductor substrate and having a plurality of wiring layers; the semiconductor substrate and the wiring layer part constitute a laminated structure in which a pixel is disposed, the pixel including a photoelectric conversion element that performs photoelectric conversion, a first charge holding part and a second charge holding part that hold charges accumulated in the photoelectric conversion element, a first transfer transistor that transfers the charges to the first charge holding part, and a second transfer transistor that transfers the charges to the second charge holding part; and a shield part surrounding a gate wiring line is formed for the gate wiring line of each of the first transfer transistor and the second transfer transistor extending in a thickness direction in the wiring layer part.

With such a sensing module according to the present technology, an action similar to that of the sensor device according to the present technology described above can be obtained.

### BRIEF DESCRIPTION OF DRAWINGS

FIG. 1 is a block diagram for explaining a configuration example of a distance measuring device including a sensor device as a first embodiment according to the present technology.

FIG. 2 is a block diagram showing a configuration example of an internal circuit of the sensor device according to the embodiment.

FIG. 3 is an equivalent circuit diagram of a pixel included in the sensor device according to the embodiment.

FIG. 4 is a plan view for explaining a schematic structure of a pixel as the first embodiment.

FIG. 5 is a cross-sectional view for explaining a schematic structure of the pixel as the first embodiment.

FIG. 6 is a plan view for explaining a structure of a shield part as the first embodiment.

FIG. 7 is a cross-sectional view of a pixel for explaining an inter-pixel wiring line serving as a connection destination of a gate wiring line.

FIG. 8 is a cross-sectional view for explaining a schematic structure of a pixel as a second embodiment.

FIG. 9 is a cross-sectional view of the pixel for explaining an inter-pixel wiring line serving as a connection destination of a gate wiring line in the second embodiment.

FIG. 10 is a cross-sectional view of a pixel for explaining an example in which a shield part is a cavity part.

FIG. 11 is a cross-sectional view of a pixel for explaining an example of a shield part including a layer including an insulating material and a layer including gas.

FIG. 12 is a plan view for explaining a modified example related to the shape of the shield part.

FIG. 13 is a plan view for explaining another modified example related to the shape of the shield part.

FIG. 14 is a plan view for explaining yet another modified example related to the shape of the shield part.

### MODE FOR CARRYING OUT THE INVENTION

Hereinafter, embodiments according to the present technology are described in the following order with reference to the accompanying drawings.
<1. First embodiment>
(1-1. Configuration of distance measuring device)
(1-2. Circuit configuration of sensor unit)
(1-3. Configuration of pixel circuit)
(1-4. Example of pixel structure)
(1-5. Shield part)
<2. Second embodiment>
<3. Modified examples>
<4. Summary of embodiments>
<5. Present technology>

### 1. First Embodiment

(1-1. Configuration of Distance Measuring Device)

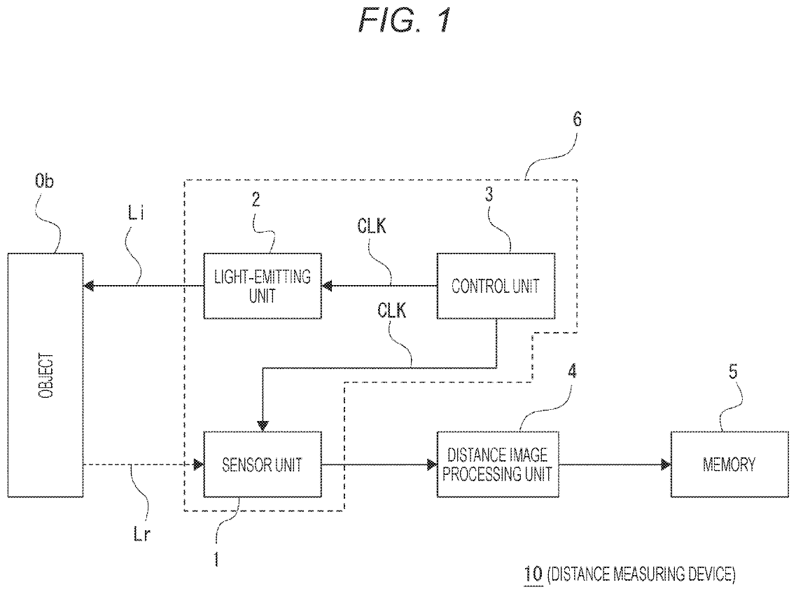

FIG. 1 is a block diagram for describing a configuration example of a distance measuring device 10 including a sensor device as a first embodiment according to the present technology. The distance measuring device 10 includes a sensor unit 1 corresponding to the sensor device as the first embodiment, a light-emitting unit 2, a control unit 3, a distance image processing unit 4, and a memory 5. In this example, the sensor unit 1, the light-emitting unit 2, and the control unit 3 are disposed on the same substrate, and are configured as a sensing module 6.

The distance measuring device 10 is a device that performs distance measurement using the time of flight (ToF) method. Specifically, the distance measuring device 10 of the present example performs the distance measurement by the indirect ToF method. The indirect ToF method is a distance measuring method of calculating the distance to an object Ob on the basis of the phase difference between irradiation light Li with respect to the object Ob and reflected light Lr obtained by reflecting the irradiation light Li by the object Ob.

The light-emitting unit 2 includes one or a plurality of light-emitting elements as a light source, and emits the irradiation light Li to the object Ob. In the present example, the light-emitting unit 2 emits, for example, infrared light having a wavelength in a range of 780 nm to 1000 nm as the irradiation light Li.

The control unit 3 controls the light emission operation of the irradiation light Li by the light-emitting unit 2. In the case of the indirect ToF method, light whose intensity is modulated so that the intensity changes at a predetermined cycle is used as the irradiation light Li. Specifically, in the present example, pulsed light is repeatedly emitted as the irradiation light Li at a predetermined cycle. Hereinafter, such a light emission cycle of the pulsed light is referred to as a “light emission cycle Cl”. In addition, a period between start timings of the light emission of the pulsed light when the pulsed light is repeatedly emitted in the light emission cycle Cl is referred to as “one modulation period Pm” or simply “modulation period Pm”.

The control unit 3 controls the light emission operation of the light-emitting unit 2 so as to emit the irradiation light Li only during a predetermined light emission period for each modulation period Pm.

Here, in the indirect ToF method, the light emission cycle Cl is relatively high speed, for example, about several tens of megahertz (MHz) to several hundreds of MHz.

The sensor unit 1 receives the reflected light Lr and outputs distance measurement information by the indirect ToF method on the basis of the phase difference between the reflected light Lr and the irradiation light Li.

As is described later, the sensor unit 1 of the present example includes a pixel array unit 11 in which a plurality of pixels Px is two-dimensionally aligned, each of the pixels Px including a photoelectric conversion element (a photodiode PD in the present example), and a first transfer transistor (for example, a transfer transistor TG1) and a second transfer transistor (for example, a transfer transistor TG2) configured to transfer charges accumulated in the photoelectric conversion element, and obtains distance measurement information from the indirect ToF method for each pixel Px.

Note that, hereinafter, the information indicating the distance measurement information (distance information) for each pixel Px as described above is referred to as a “distance image”.

Here, as is known, in the indirect ToF method, the signal charges accumulated in the photoelectric conversion element in the pixel Px are distributed to two floating diffusions (FD) by the first transfer transistor and the second transfer transistor which are alternately turned on. At this time, the cycle in which the first transfer transistor and the second transfer transistor are alternately turned on is set to be the same as the light emission cycle Cl of the light-emitting unit 2. That is, each of the first transfer transistor and the second transfer transistor is turned on once in each modulation period Pm, and the distribution of the signal charges to the two floating diffusions as described above is repeatedly performed in each modulation period Pm.

In the present example, the first transfer transistor (transfer transistor TG1) is in the on state in the light emission period of the irradiation light Li in the modulation period Pm, and the second transfer transistor (transfer transistor TG2) is in the on state in the non-light emission period of the irradiation light Li in the modulation period Pm.

As described above, because the light emission cycle Cl is set to a relatively high speed, the signal charges accumulated in each floating diffusion by one distribution using the first and second transfer transistors as described above is relatively small. For this reason, in the indirect ToF method, the emission of the irradiation light Li is repeated about several thousands of times to several tens of thousands of times for one distance measurement (that is, in obtaining one piece of distance image), and the sensor unit 1 repeatedly distributes the signal charges to each floating diffusion using the first and second transfer transistors as described above while the irradiation light Li is repeatedly emitted in this manner.

As understood from the above description, in the sensor unit 1, the first transfer transistor and the second transfer transistor are driven at the timing synchronized with the light emission cycle of the irradiation light Li for each pixel Px. For this synchronization, the control unit 3 controls the light reception operation by the sensor unit 1 and the light emission operation by the light-emitting unit 2 on the basis of a common clock CLK.

The distance image processing unit 4 inputs the distance image obtained by the sensor unit 1, performs predetermined signal processing such as compression encoding, and outputs the distance image to the memory 5.

The memory 5 is a storage device such as a flash memory, a solid state drive (SSD), or a hard disk drive (HDD), and stores the distance image processed by the distance image processing unit 4.

(1-2. Circuit Configuration of Sensor Unit)

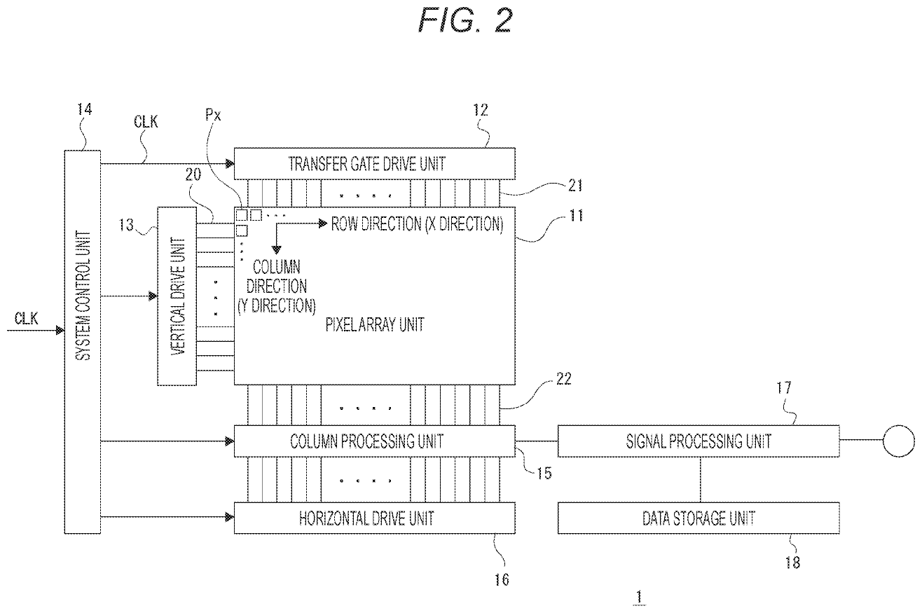

FIG. 2 is a block diagram showing a configuration example of an internal circuit of the sensor unit 1.

As illustrated, the sensor unit 1 includes the pixel array unit 11, a transfer gate drive unit 12, a vertical drive unit 13, a system control unit 14, a column processing unit 15, a horizontal drive unit 16, a signal processing unit 17, and a data storage unit 18.

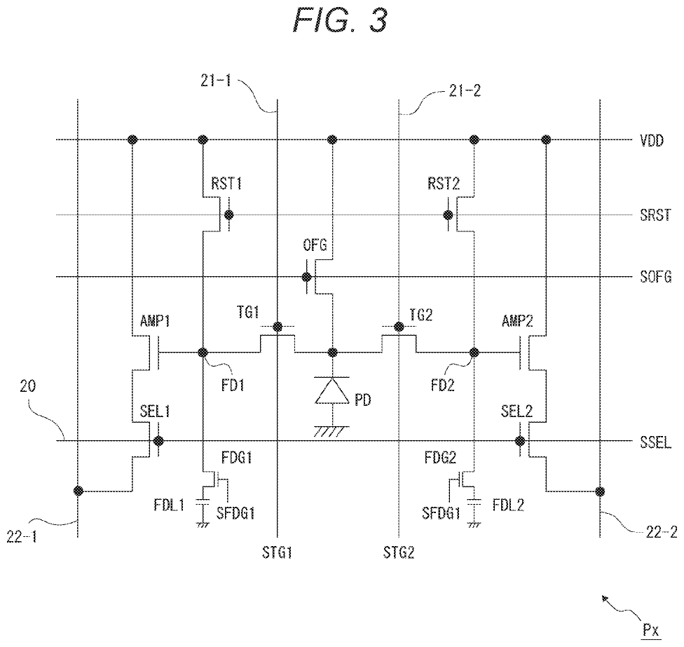

The pixel array unit 11 has a configuration in which the plurality of pixels Px is two-dimensionally aligned in a matrix in a row direction and a column direction. Each pixel Px includes a photodiode PD described later as a photoelectric conversion element. Note that details of the circuit configuration of the pixel Px is described again with reference to FIG. 3.

Here, the row direction refers to the alignment direction of the pixels Px in the horizontal direction, and the column direction refers to the alignment direction of the pixels Px in the vertical direction. In the drawing, the row direction is a horizontal direction, and the column direction is a vertical direction.

Note that, hereinafter, the row direction may be referred to as an “X direction”, and the column direction may be referred to as a “Y direction”. In addition, a direction orthogonal to the X-Y plane (that is, the thickness direction of the sensor unit 1) may be described as a “Z direction”.

In the pixel array unit 11, with respect to the matrix pixel array, a row drive line 20 is wired along the row direction for each pixel row, and two gate drive lines 21 and two vertical signal lines 22 are wired along the column direction for each pixel column. For example, the row drive line 20 transmits a drive signal configured to perform driving at the time of reading a signal from the pixel Px. Note that, in FIG. 2, the row drive line 20 is shown as one wiring line, but is not limited to one line. One end of the row drive line 20 is connected to an output end corresponding to each row of the vertical drive unit 13.

The system control unit 14 includes a timing generator that generates various timing signals and the like, and performs drive control of the transfer gate drive unit 12, the vertical drive unit 13, the column processing unit 15, the horizontal drive unit 16, and the like on the basis of the various timing signals generated by the timing generator.

The transfer gate drive unit 12 drives two transfer transistors provided for each pixel Px through the gate drive lines 21 provided in two for each pixel column as described above under the control of the system control unit 14.

As described above, the two transfer transistors are alternately turned on every modulation period Pm. Therefore, the system control unit 14 supplies the clock CLK input from the control unit 3 shown in FIG. 1 to the transfer gate drive unit 12, and the transfer gate drive unit 12 drives the two transfer transistors on the basis of the clock CLK.

The vertical drive unit 13 includes a shift register, an address decoder, and the like, and drives the pixels Px of the pixel array unit 11 at the same time for all the pixels or in units of rows. That is, the vertical drive unit 13 constitutes a drive control unit that controls the operation of each pixel Px of the pixel array unit 11 together with the system control unit 14 that controls the vertical drive unit 13.

The detection signal output (read) from each pixel Px of the pixel row according to the drive control by the vertical drive unit 13, specifically, a signal corresponding to the signal charge accumulated in each of the two floating diffusions provided for each pixel Px is input to the column processing unit 15 through the corresponding vertical signal line 22. The column processing unit 15 performs predetermined signal processing on the detection signal read from each pixel Px through the vertical signal line 22, and temporarily holds the detection signal after the signal processing. Specifically, the column processing unit 15 performs noise removal processing, analog to digital (A/D) conversion processing, and the like as the signal processing.

Here, reading of two detection signals (detection signals for each floating diffusion) from each pixel Px is performed once for every predetermined number of repeated light emission of the irradiation light Li (every several thousands to tens of thousands of times of repeated light emission described above).

Therefore, the system control unit 14 controls the vertical drive unit 13 on the basis of the clock CLK to cause the reading timing of the detection signal from each pixel Px to become the timing for every repeated light emission of the irradiation light Li for a predetermined number of times as described above.

The horizontal drive unit 16 includes a shift register, an address decoder, and the like, and sequentially selects a unit circuit corresponding to the pixel column of the column processing unit 15. By the selective scanning by the horizontal drive unit 16, the detection signal subjected to the signal processing for each unit circuit in the column processing unit 15 are sequentially output.

The signal processing unit 17 has at least an arithmetic processing function, and performs various signal processing such as distance calculation processing corresponding to the indirect ToF method on the basis of the detection signal output from the column processing unit 15. Note that a known method can be used as a method of calculating distance information by the indirect ToF method on the basis of two types of detection signals (detection signals for each floating diffusion) for each pixel Px, and the description thereof is omitted here.

The data storage unit 18 temporarily stores data necessary for the signal processing in the signal processing unit 17.

The sensor unit 1 configured as described above outputs the distance image indicating the distance to the object Ob for each pixel Px. The distance measuring device 10 including such a sensor unit 1 can be applied to, for example, an on-vehicle system that is mounted on a vehicle and measures a distance to an object Ob outside the vehicle, a gesture recognition device that measures a distance to an object such as a hand of a user and recognizes a gesture of the user on the basis of the measurement result, and the like.

(1-3. Configuration of Pixel Circuit)

FIG. 3 shows an equivalent circuit of the pixel Px two-dimensionally aligned in the pixel array unit 11.

The pixel Px includes one photodiode PD as a photoelectric conversion element and one charge discharge transistor OFG. Furthermore, the pixel Px includes two transfer transistors TG as transfer gate elements, two floating diffusions FD, two reset transistors RST, two switching transistors FDG, two additional capacitors FDL, two amplification transistors AMP, and two selection transistors SEL.

Here, in a case where one is to be distinguished from the other among the two that are provided in the pixel Px for each of the transfer transistors TG, the floating diffusions FD, the reset transistors RST, the switching transistors FDG, the additional capacitors FDL, the amplification transistors AMP, and the selection transistors SEL, as shown in FIG. 3, the above constitutional elements are denotes as the transfer transistors TG1 and TG2, the floating diffusions FD1 and FD2, the switching transistors FDG1 and FDG2, the additional capacitors FDL1 and FDL2, the reset transistors RST1 and RST2, the amplification transistors AMP1 and AMP2, and the selection transistors SEL1 and SEL2.

The charge discharge transistor OFG, the transfer transistor TG, the reset transistor RST, the switching transistor FDG, the amplification transistor AMP, and the selection transistor SEL include, for example, N-type MOS transistors.

The charge discharge transistor OFG is brought into a conductive state when a charge discharge signal SOFG to be supplied to the gate thereof is turned on. When the charge discharge transistor OFG becomes conductive, the photodiode PD is clamped at a predetermined reference potential VDD, and the accumulated charges are reset.

Note that the charge discharge signal SOFG is supplied from, for example, the vertical drive unit 13.

The transfer transistor TG1 becomes conductive when a transfer drive signal STG1 to be supplied to the gate thereof is turned on, and transfers the signal charges accumulated in the photodiode PD to the floating diffusion FD1. The transfer transistor TG2 becomes conductive when a transfer drive signal STG2 to be supplied to the gate thereof is turned on, and transfers the signal charges accumulated in the photodiode PD to the floating diffusion FD2.

The transfer drive signals STG1 and STG2 are supplied from the transfer gate drive unit 12 through gate drive lines 21-1 and 21-2 provided as one of the gate drive lines 21 shown in FIG. 2.

The floating diffusions FD1 and FD2 are charge holding parts that temporarily hold the charge transferred from the photodiode PD.

The switching transistor FDG1 is brought into a conductive state in a response to a FD drive signal SFDG1 to be supplied to the gate electrode thereof being turned on, which causes the additional capacitor FDL1 to be connected to the floating diffusion FD1. The switching transistor FDG2 is brought into a conductive state in a response to a FD drive signal SFDG2 to be supplied to the gate electrode thereof being turned on, which causes the additional capacitor FDL2 to be connected to the floating diffusion FD2.

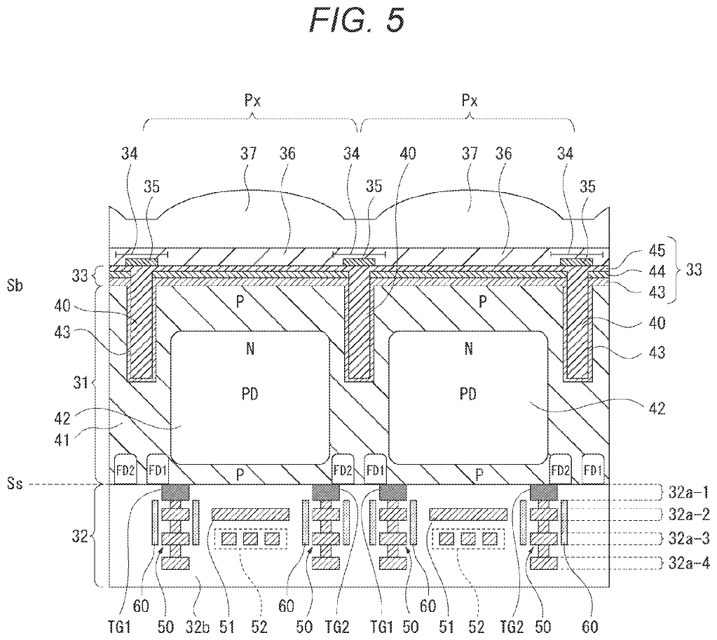

In the present example, the additional capacitors FDL1 and FDL2 include a capacitance generation part 52 in FIG. 5 described later.

The reset transistor RST1 is brought into a conductive state when a reset signal SRST to be supplied to the gate thereof is turned on, and resets the potential of the floating diffusion FD1 to a reference potential VDD. Similarly, the reset transistor RST2 is brought into a conductive state when a reset signal SRST to be supplied to the gate thereof is turned on, and resets the potential of the floating diffusion FD2 to the reference potential VDD.

Note that when the reset transistors RST1 and RST2 are brought into a conductive state, the switching transistors FDG1 and FDG2 are also brought into a conductive state at the same time, and the additional capacitors FDL1 and FDL2 are also reset.

The reset signal SRST is supplied from, for example, the vertical drive unit 13.

Here, for example, when the incident light is large in amount with high illuminance, the vertical drive unit 13 brings the switching transistors FDG1 and FDG2 into a conductive state, connects the floating diffusion FD1 to the additional capacitor FDL1, and connects the floating diffusion FD2 to the additional capacitor FDL2. With this arrangement, the charge transferred from the photodiode PD can be accumulated more at the time of high illuminance.

On the other hand, when the incident light is small in amount with low illuminance, the vertical drive unit 13 brings the switching transistors FDG1 and FDG2 into a non-conductive state, and separates the additional capacitors FDL1 and FDL2 from the floating diffusions FD1 and FD2, respectively. With this arrangement, the conversion efficiency can be increased.

Note that, in the pixel Px, the additional capacitors FDL1 and FDL2, and the switching transistors FDG1 and FDG2 that control the connection of the additional capacitors, may be omitted, but a high dynamic range can be achieved by providing the additional capacitors FDL and selectively using the same according to the amount of incident light.

The amplification transistor AMP1 has a source connected to the vertical signal line 22-1 via the selection transistor SEL1 and a drain connected to the reference potential VDD (constant current source) to constitute a source follower circuit. The amplification transistor AMP2 has a source connected to the vertical signal line 22-2 via the selection transistor SEL2 and a drain connected to the reference potential VDD (constant current source) to constitute a source follower circuit.

Here, the vertical signal lines 22-1 and 22-2 are provided as one of the vertical signal lines 22 shown in FIG. 2, respectively.

The selection transistor SEL1 is connected between the source of the amplification transistor AMP1 and the vertical signal line 22-1, brought into a conductive state when a selection signal SSEL to be supplied to the gate thereof is turned on, and outputs the charge held in the floating diffusion FD1 to the vertical signal line 22-1 via the amplification transistor AMP1.

The selection transistor SEL2 is connected between the source of the amplification transistor AMP2 and the vertical signal line 22-2, brought into a conductive state when a selection signal SSEL to be supplied to the gate thereof is turned on, and outputs the charge held in the floating diffusion FD2 to the vertical signal line 22-2 via the amplification transistor AMP1.

Note that the selection signal SSEL is supplied from the vertical drive unit 13 via the row drive line 20.

The operation of the pixel Px is briefly described.

First, before the reception of light is started, a reset operation of resetting charges in the pixel Px is performed in all the pixels. That is, for example, the charge discharge transistor OFG, each of the reset transistors RST, each of the switching transistors FDG, and each of the transfer transistors TG are turned on (conductive state), and the charges accumulated in the photodiode PD, each of the floating diffusions FD, and each of the additional capacitors FDL are reset.

After the accumulated charges are reset, the light reception operation for distance measurement is started in all the pixels. The light reception operation here means a light reception operation performed for one distance measurement. That is, during the light reception operation, the operation of alternately turning on the transfer transistors TG1 and TG2 is repeated a predetermined number of times (in this example, about several thousands of times to several tens of thousands of times). Hereinafter, a period of the light reception operation performed for such one distance measurement is referred to as a “light reception period Pr”.

In the light reception period Pr, in one modulation period Pm of the light-emitting unit 2, for example, a period in which the transfer transistor TG1 is on (that is, a period in which the transfer transistor TG2 is off) is continued over the light emission period of the irradiation light Li, and thereafter, a remaining period, that is, a non-light emission period of the irradiation light Li, is regarded as a period in which the transfer transistor TG2 is on (that is, a period in which the transfer transistor TG1 is off). That is, in the light reception period Pr, the operation of distributing the charges of the photodiode PD to the floating diffusions FD1 and FD2 is repeated a predetermined number of times within one modulation period Pm.

Then, when the light reception period Pr ends, each pixel Px of the pixel array unit 11 is selected line by line. In the selected pixel Px, the selection transistors SEL1 and SEL2 are turned on. With this arrangement, the charges accumulated in the floating diffusion FD1 are output to the column processing unit 15 via the vertical signal line 22-1. In addition, the charges accumulated in the floating diffusion FD2 are output to the column processing unit 15 via the vertical signal line 22-2.

As described above, one light reception operation ends, and the next light reception operation starting from the reset operation is executed.

Here, the reflected light received by the pixel Px is delayed according to the distance to the object Ob from the timing at which the light-emitting unit 2 emits the irradiation light Li. Because the distribution ratio of the charges accumulated in the two floating diffusions FD1 and FD2 changes depending on the delay time corresponding to the distance to the object Ob, the distance to the object Ob can be obtained from the distribution ratio of the charges accumulated in the two floating diffusions FD1 and FD2.

(1-4. Example of Pixel Structure)

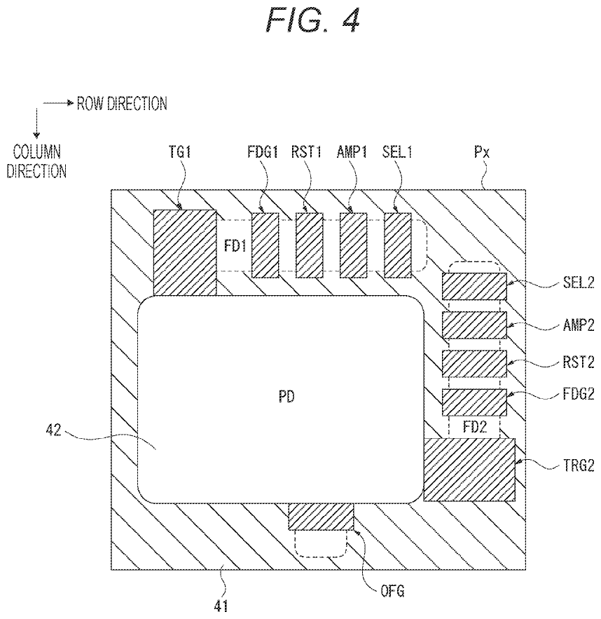

FIG. 4 is a plan view for explaining a schematic structure of the pixel Px.

Note that the horizontal direction in FIG. 4 corresponds to the row direction (X direction) in FIG. 1, and the vertical direction corresponds to the column direction (Y direction) in FIG. 1.

The pixel Px has a rectangular shape in plan view shown in FIG. 4.

The photodiode PD is arranged substantially at the center of the pixel Px in a semiconductor substrate (a semiconductor substrate 31 described later). The photodiode PD includes an N-type semiconductor region 42. In plan view, a P-type semiconductor region 41 is disposed around the photodiode PD which is the N-type semiconductor region 42.

On the outer side of the photodiode PD, the transfer transistor TG1, the switching transistor FDG1, the reset transistor RST1, the amplification transistor AMP1, and the selection transistor SEL1 are linearly arranged along a predetermined side among four sides of the pixel Px, and the transfer transistor TG2, the switching transistor FDG2, the reset transistor RST2, the amplification transistor AMP2, and the selection transistor SEL2 are linearly arranged along another side among the four sides of the pixel Px.

Moreover, the charge discharge transistor OFG is arranged in the vicinity of another side different from the two sides of the pixel Px on which the transfer transistors TG, the reset transistors RST, the switching transistors FDG, the amplification transistors AMP, and the selection transistors SEL are disposed.

Note that the arrangement of each component of the pixel Px shown in FIG. 4 is not limited to this example, and may have another arrangement.

FIG. 5 is a cross-sectional view for explaining a schematic structure of the pixel Px.

First, as a premise, the sensor unit 1 of the present example is configured as a so-called back-illuminated sensor device that receives incident light from the side of a back surface Sb (upper side in the drawing) of the semiconductor substrate 31 on which the photodiodes PD are disposed in units of pixels.

The sensor unit 1 includes the semiconductor substrate 31 and a wiring layer part 32 disposed on the side of a front surface Ss thereof.

The semiconductor substrate 31 includes, for example, silicon (Si), and has a thickness of, for example, about 1 μm to 6 μm. In the semiconductor substrate 31, for example, the N-type (second conductivity type) semiconductor region 42 is disposed in the P-type (first conductivity type) semiconductor region 41 in units of pixels to allow the photodiodes PD to be disposed in units of pixels. The P-type semiconductor region 41 provided on both the front and back surface sides of the semiconductor substrate 31 also serves as a hole charge accumulation region for suppressing dark current.

In FIG. 5, the back surface Sb of the semiconductor substrate 31 is a light incident surface on which light is incident. An antireflection film 33 is disposed on the back surface Sb of the semiconductor substrate 31.

The antireflection film 33 has, for example, a laminated structure in which a fixed charge film and an oxide film are laminated, and for example, an insulating thin film having a high dielectric constant (High-k) produced by an atomic layer deposition (ALD) method can be used. Specifically, hafnium oxide (HfO₂), aluminum oxide (Al₂O₃), titanium oxide (TiO₂), strontium titan oxide (STO), or the like can be used. In the example in FIG. 5, the antireflection film 33 is formed by laminating a hafnium oxide film 43, an aluminum oxide film 44, and a silicon oxide film 45.

An inter-pixel light-shielding film 35 that prevents incident light from being incident on the adjacent pixel is disposed on the antireflection film 33 and at a boundary part 34 (hereinafter, also referred to as a “pixel boundary part 34”) between the pixels Px adjacent to each other. The inter-pixel light-shielding film 35 has a lattice shape so as to open the photodiode PD of each pixel Px.

The material of the inter-pixel light-shielding film 35 only needs to be a material that shields light, and for example, a metal material such as tungsten (W), aluminum (Al), or copper (Cu) can be used.

The inter-pixel light-shielding film 35 prevents the light intended to be incident only on one pixel Px from leaking into the other pixel Px, between the pixels Px adjacent to each other.

A planarization film 36 is disposed on the inter-pixel light-shielding film 35 and on the antireflection film 33 where the inter-pixel light-shielding film 35 is not disposed, so that the surface on the back surface Sb side of the semiconductor substrate 31 is planarized. The planarization film 36 can include, for example, an insulating film such as silicon oxide (SiO₂), silicon nitride (SiN), or silicon oxynitride (SiON), or an organic material such as resin.

On the upper surface of the planarization film 36, an on-chip lens (microlens) 37 is disposed for each pixel. The on-chip lens 37 includes, for example, a resin material such as a styrene resin, an acrylic resin, a styrene-acrylic copolymer resin, or a siloxane resin. The light condensed by the on-chip lens 37 is efficiently incident on the photodiode PD.

Furthermore, at the pixel boundary part 34 on the back surface Sb side of the semiconductor substrate 31, an inter-pixel separation part 40 that electrically separates the adjacent pixels Px from each other is disposed from the back surface Sb side of the semiconductor substrate 31 to a predetermined depth in the substrate thickness direction. An outer peripheral part including a bottom surface and a side wall of the inter-pixel separation part 40 is covered with the hafnium oxide film 43 which is a part of the antireflection film 33. The inter-pixel separation part 40 has a function of electrically separating the pixels Px from each other so that leakage of signal charges does not occur between the pixels Px.

Here, the inter-pixel separation part 40 can be formed by forming a trench (groove) in the semiconductor substrate 31 so as to surround a disposing region of the photodiode PD, and embedding an insulating material (the silicon oxide film 45 in this example) in the trench (so-called trench isolation). Specifically, the inter-pixel separation part 40 can be configured as, for example, Reversed Deep Trench Isolation (RDTI), Reversed Full Trench Isolation (RFTI), a Front Deep Trench Isolation (FDTI), Front Full Trench Isolation (FFTI), or the like.

Here, “front” and “reversed” mean a difference in whether cutting for forming the trench is performed from the front surface Ss side or the back surface Sb side of the semiconductor substrate 31. In addition, “deep” and “full” represent the trench depth (groove depth), where “full” means that the trench penetrates the semiconductor substrate 31, and “deep” means that the trench is formed at a depth that does not penetrate the semiconductor substrate 31.

FIG. 5 exemplifies a structure corresponding to the RDTI or the RFTI in which the trench is formed from the back surface Sb side.

Here, in a case where the trench is formed in the semiconductor substrate 31, the width of the trench tends to gradually decrease toward the advancing direction side of the cutting. Therefore, in a case where the trench is formed from the front surface Ss side as in the FDTI or the FFTI, the inter-pixel separation part 40 is characterized that the width is narrower on the back surface Sb side than on the front surface Ss side. On the other hand, in a case where the trench is formed from the back surface Sb side as in the RDTI or the RFTI, the inter-pixel separation part 40 is characterized that the width is narrower on the front surface Ss side than on the back surface Sb side.

On the front surface Ss of the semiconductor substrate 31 on which the wiring layer part 32 is disposed, two transfer transistors TG1 and TG2 are disposed for one photodiode PD disposed in each pixel Px. Furthermore, on the front surface Ss side of the semiconductor substrate 31, the floating diffusions FD1 and FD2 as charge accumulation parts that temporarily hold the charges transferred from the photodiodes PD include high-concentration N-type semiconductor regions (N-type diffusion regions).

The wiring layer part 32 includes a plurality of wiring layers 32a and interlayer insulating films 32b therebetween. FIG. 5 shows an example in which the wiring layer part 32 includes four wiring layers 32a, which are a first wiring layer 32a-1, a second wiring layer 32a-2, a third wiring layer 32a-3, and a fourth wiring layer 32a-4.

In the wiring layer part 32, the wiring layer 32a closest to the front surface Ss of the semiconductor substrate 31 is the first wiring layer 32a-1. On the first wiring layer 32a-1 (that is, a layer in contact with the front surface Ss of the semiconductor substrate 31), electrodes of the respective pixel transistors including the transfer transistors TG1 and TG2 described above (the reset transistors RST, the selection transistors SEL, and the like described above) described above are disposed. In this sense, the first wiring layer 32a-1 can be referred to as an electrode disposing layer of a pixel transistor.

The second wiring layer 32a-2 is the wiring layer 32a laminated on the first wiring layer 32a-1 with the interlayer insulating film 32b interposed therebetween, the third wiring layer 32a-3 is the wiring layer 32a laminated on the second wiring layer 32a-2 with the interlayer insulating film 32b interposed therebetween, and the fourth wiring layer 32a-4 is the wiring layer 32a laminated on the third wiring layer 32a-3 with the interlayer insulating film 32b interposed therebetween.

In the wiring layer part 32, the electrode (gate electrode) of each transfer transistor TG disposed in the first wiring layer 32a-1 is connected to an inter-pixel wiring line (not illustrated in FIG. 5) configured to drive the gate and disposed in the fourth wiring layer 32a-4 via a gate wiring line 50 extending in the thickness direction (Z direction). This inter-pixel wiring line corresponds to the gate drive line 21 (21-1 and 21-2) shown in FIGS. 2 and 3 above, and is disposed in the fourth wiring layer 32a-4 farthest from the semiconductor substrate 31 in this example.

As described above, each transfer transistor TG is driven on the basis of the transfer drive signal STG supplied via the inter-pixel wiring line as the gate drive line 21.

In the present example, the gate wiring line 50 includes wiring lines disposed in the second wiring layer 32a-2 and the third wiring layer 32a-3 and vias connecting the wiring layers 32a to each other. In the gate wiring line 50, the wiring line disposed in each of the second wiring layer 32a-2 and the third wiring layer 32a-3 is a wiring line extending in the in-plane direction on the inner side of a shield part 60 described later. For confirmation, the in-plane direction referred to herein means an in-plane direction orthogonal to the thickness direction.

Furthermore, in the wiring layer part 32, in the second wiring layer 32a-2, a wiring line including metal such as copper or aluminum is disposed as a light-shielding/reflecting member 51 in a region located below the disposing region of the photodiode PD, in other words, in a region at least partially overlapping with the disposing region of the photodiode PD in plan view.

The light-shielding/reflecting member 51 shields light that has entered the semiconductor substrate 31 from the light incident surface via the on-chip lens 37 and has passed through the semiconductor substrate 31 without being photoelectrically converted in the semiconductor substrate 31, and causes the light not to pass through the third wiring layer 32a-3 and the fourth wiring layer 32a-4 located below the light-shielding/reflecting member. This light-shielding function can suppress the light (infrared light in this example), which has not been photoelectrically converted in the semiconductor substrate 31 and has been transmitted through the semiconductor substrate 31, from being scattered in the wiring layer 32a below the second wiring layer 32a-2 and entering the neighboring pixel. With this arrangement, the light can be prevented from being erroneously detected by the neighboring pixel.

In addition, the light-shielding/reflecting member 51 also has a function of reflecting the light, which has entered the semiconductor substrate 31 from the light incident surface via the on-chip lens 37 and has passed through the semiconductor substrate 31 without being photoelectrically converted in the semiconductor substrate 31, by the light-shielding/reflecting member 51 and causes the light to be incident again in the semiconductor substrate 31. Therefore, the light-shielding/reflecting member 51 is also said to be a reflecting member. This reflecting function can increase the amount of light photoelectrically converted in the semiconductor substrate 31, and can improve the quantum efficiency (QE), that is, the sensitivity of the pixel Px to light.

Note that the light-shielding/reflecting member 51 may have a structure that reflects or shields the light with polysilicon, an oxide film, or the like in addition to the metal material.

Furthermore, the light-shielding/reflecting member 51 may not include only one wiring layer 32a, but may include, for example, a plurality of the wiring layers 32a formed in a lattice shape by the second wiring layer 32a-2 and the third wiring layer 32a-3, or the like.

A predetermined wiring layer 32a among the plurality of wiring layers 32a of the wiring layer part 32, specifically, the third wiring layer 32a-3 in this example includes, for example, a capacitance generation part 52 formed by patterning the wiring layer in a comb tooth shape. The capacitance generation part 52 functions as the additional capacitor FDL described above.

Note that the light-shielding/reflecting member 51 and the capacitance generation part 52 may be disposed in the same wiring layer 32a, but in a case where the above two are disposed in the different wiring layers 32a, the capacitance generation part 52 is disposed in a layer farther from the semiconductor substrate 31 than the light-shielding/reflecting member 51. In other words, the light-shielding/reflecting member 51 is disposed closer to the semiconductor substrate 31 than the capacitance generation part 52.

Here, in the wiring layer part 32 of the present example, the shield part 60 is provided for each gate wiring line 50, but this shield part 60 is described again later.

As described above, the sensor unit 1 of the present example has a back-illuminated structure in which the semiconductor substrate 31 as a semiconductor layer is arranged between the on-chip lens 37 and the wiring layer part 32, and incident light is made incident on the photodiode PD from the back surface Sb side on which the on-chip lens 37 is disposed.

(1-5. Shield Part)

Here, as described above, in the sensor unit 1 using the indirect ToF method, because the transfer transistors TG1 and TG2 forming a pair are driven at high speed so as to repeat on/off in a short cycle of about several tens of MHz to several hundreds of MHz (for example, about 10 MHz to 200 MHz), there is a problem that power consumption increases.

In order to reduce the power consumption, it is effective to reduce either a gate capacitance Cg of the transfer transistor TG or a wiring capacitance Cw of the wiring line (that is, the gate wiring line 50) connected to the gate electrode. Specifically, by denoting the capacitance as C (the gate capacitance Cg+the wiring capacitance Cw) and the drive voltage (swing width of the transfer transistor) as V, a power consumption W is calculated as follows:

W=½*·(C·V)²

Therefore, the power consumption W can be reduced by reducing the wiring capacitance Cw.

In order to reduce the wiring capacitance Cw of the gate wiring line 50, the shield part 60 shown in FIG. 5 is disposed in the sensor unit 1 of the present embodiment.

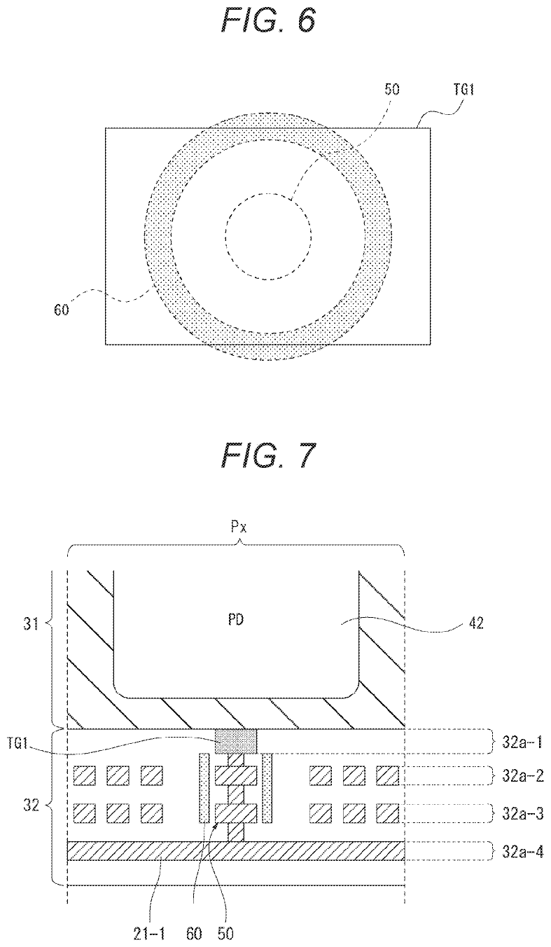

FIG. 6 is a plan view for explaining the structure of the shield part 60, and exemplifies a positional relationship among the transfer transistor TG1, the gate wiring line 50, and the shield part 60 in plan view of the wiring layer part 32 from the semiconductor substrate 31 side.

Here, the shield part 60 is also disposed on the transfer transistor TG2 side, but in this case as well, the structure of the shield part 60 is similar, and thus illustration is omitted.

As illustrated in the drawing, the shield part 60 is disposed so as to surround the gate wiring line 50 in plan view. Specifically, the shield part 60 in the present example has an annular shape in plan view as illustrated in the drawing and surrounds the gate wiring line 50. Here, being annular in plan view can be rephrased as having an annular cross-sectional shape in the in-plane direction.

In this example, the shield part 60 includes an insulating material different from the material of the interlayer insulating film 32b. Specifically, the shield part 60 in this case includes a Low-k material (low dielectric constant material).

Here, examples of the Low-k material include SiOF obtained by adding fluorine to SiO₂. Alternatively, examples of the Low-k material include a SiOCH-based material obtained by adding hydrocarbon to SiO₂, an organic polymer-based material, and a porous silica-based material.

By providing the shield part 60 described above for the gate wiring line 50, the capacitive load on the gate wiring line 50 from the surrounding wiring lines can be reduced, and the wiring capacitance Cw of the gate wiring line 50 can be reduced.

Here, the shield part 60 of the present example is formed by digging a trench into the wiring layer part 32.

Specifically, the wiring layer part 32 is formed by laminating the second wiring layer 32a-2, the third wiring layer 32a-3, and the fourth wiring layer 32a-4 on the front surface Ss of the semiconductor substrate 31 on which the electrodes of the pixel transistors are disposed while interposing the interlayer insulating films 32b between the wiring layers, and the shield part 60 is formed by digging a trench from the predetermined wiring layer 32a toward the semiconductor substrate 31 side at the stage of laminating the predetermined wiring layer 32a, in such a forming process of the wiring layer part 32. At this time, the trench is formed by, for example, dry etching or the like.

The formed trench is filled with an insulating material (the Low-k material in this example) as a shield material to form the shield part 60.

In this example, the shield part 60 is disposed across the plurality of wiring layers 32a. Specifically, the shield part 60 in this case is disposed across the third wiring layer 32a-3 to the first wiring layer 32a-1.

By having the shield part 60 disposed across the plurality of wiring layers 32a in this manner, the range in which the shield part 60 covers the gate wiring line 50 in the laminating direction of the wiring layer part 32 is widened, and the effect of reducing the wiring capacitance of the gate wiring line can be enhanced.

Here, as described above, in the present example, the gate drive line 21 (the inter-pixel wiring line) to which the gate wiring line 50 is connected is disposed in the fourth wiring layer 32a-4 (farthest wiring layer) farthest from the semiconductor substrate 31.

FIG. 7 is a cross-sectional view of the pixel Px for explaining the gate drive line 21 as the inter-pixel wiring line. Note that the cross-sectional view in FIG. 7 illustrates a cross section in a case where the pixel Px is cut in a direction different from the cross-sectional view in FIG. 5. Here, the relationship among the transfer transistor TG1, the gate wiring line 50 thereof, and the gate drive line 21-1 is exemplified, but the relationship among the transfer transistor TG2, the gate wiring line 50 thereof, and the gate drive line 21-2 is also similar to that in the present drawing, and thus illustration thereof is omitted.

In a case where the gate drive line 21-1 as the inter-pixel wiring line is disposed in the fourth wiring layer 32a-4, the shield part 60 cannot be formed by digging a trench from the fourth wiring layer 32a-4. This is because, if a trench is formed from the fourth wiring layer 32a-4, in the fourth wiring layer 32a-4, the gate wiring line 50 and the gate drive line 21-1 are shielded by the shield part 60 and cannot be electrically connected to each other.

Therefore, according to the present example in which the shield part 60 is formed by digging the trench from the third wiring layer 32a-3 adjacent to the fourth wiring layer 32a-4, the range in which the shield part 60 covers the gate wiring line 50 in the laminating direction of the wiring layer part 32 can be maximized, and the effect of reducing the wiring capacitance Cw can be enhanced.

### 2. Second Embodiment

Next, a second embodiment is described.

In the second embodiment, a gate wiring line 50A including a through via is provided instead of the gate wiring line 50.

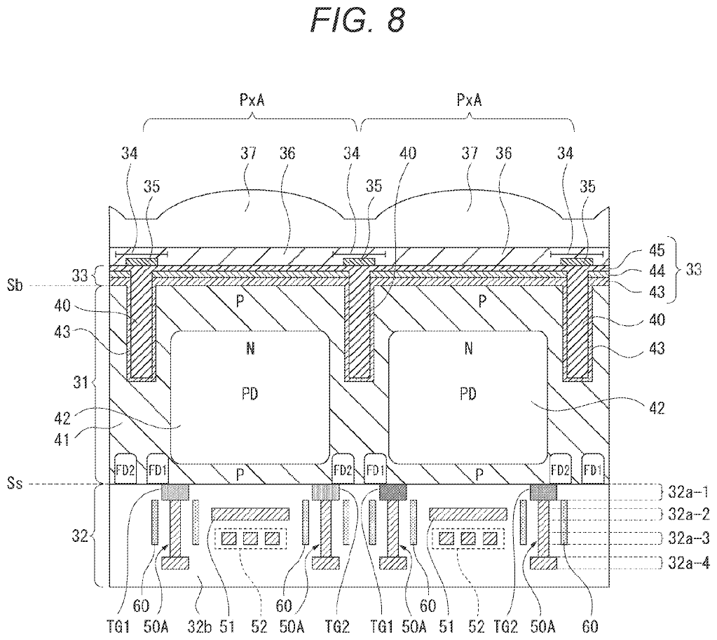

FIG. 8 is a cross-sectional view for explaining a schematic structure of a pixel PxA as the second embodiment.

Note that, in the following description, the same reference numerals are given to portions similar to those already described, and description thereof is omitted.

As illustrated, in the pixel PxA of the second embodiment, as a gate wiring line of each of transfer transistors TG1 and TG2, the gate wiring line 50A including a through via penetrating from a first wiring layer 32a-1 to a fourth wiring layer 32a-4 is provided.

By forming the gate wiring line 50A by including such a through via, the wiring line does not need to be formed in the in-plane direction as in the gate wiring line 50 in the first embodiment, and thus the gate wiring line can be made thin.

Therefore, the effect of reducing the wiring capacitance of the gate wiring line can be enhanced.

Here, in the gate wiring line 50 in the first embodiment, because the wiring line in the in-plane direction is formed in the second wiring layer 32a-2 and the third wiring layer 32a-3, at the time of forming the gate wiring line in the region on the inner side of the shield part 60 in the forming process of a wiring layer part 32, the same process as the forming process of the wiring line in the outer region of the shield part 60 can be applied, the process including forming of the via for one layer after the wiring line (to be dummy) is formed in each wiring layer 32a of the second wiring layer 32a-2 and the third wiring layer 32a-3.

Therefore, there is an advantage that the manufacturing efficiency of the sensor device can be improved in reducing the wiring capacitance of the gate wiring line.

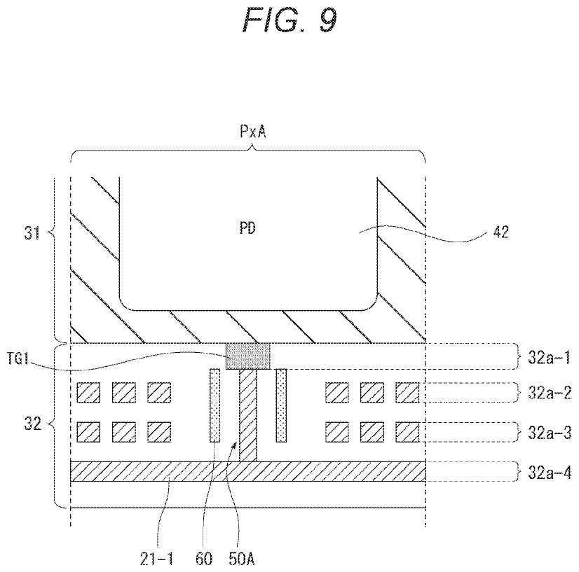

FIG. 9 is a cross-sectional view of the pixel PxA for explaining a gate drive line 21 as the inter-pixel wiring line. Note that the cross-sectional view in FIG. 9 shows, similarly to the relationship between FIGS. 5 and 7 described above, a cross section in a case where the pixel PxA is cut in a direction different from the cross-sectional view in FIG. 8.

As exemplified in FIG. 9, the gate wiring line 50A including the through via may have a configuration in which the gate electrode of the transfer transistor TG is directly connected to the gate drive line 21 disposed in the fourth wiring layer 32a-4.

### 3. Modified Examples

Here, the embodiment is not limited to the specific example exemplified above, and configurations as various modified examples can be adopted.

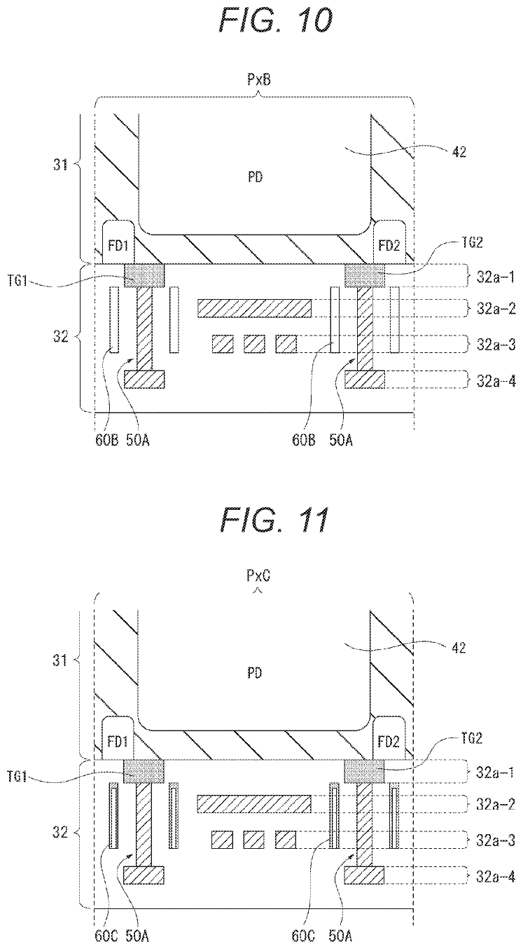

For example, as shown in the cross-sectional view of a pixel PxB shown in FIG. 10, a configuration in which a shield part 60B as a cavity part (that is, filled with gas such as air) is provided can be adopted.

With this arrangement, in a case where the shield part is formed by digging the trench into the wiring layer part 32, a process of filling the trench with the insulating material becomes unnecessary.

Alternatively, as shown in a cross-sectional view of a pixel PxC shown in FIG. 11, a configuration in which a shield part 60C having a layer of insulating material such as a Low-k material and a layer of gas such as air is provided can be adopted. Specifically, in the example shown in FIG. 11, the configuration of the shield part 60C in which the outer edge part is a Low-k material layer and the inner side part is an air layer is exemplified.

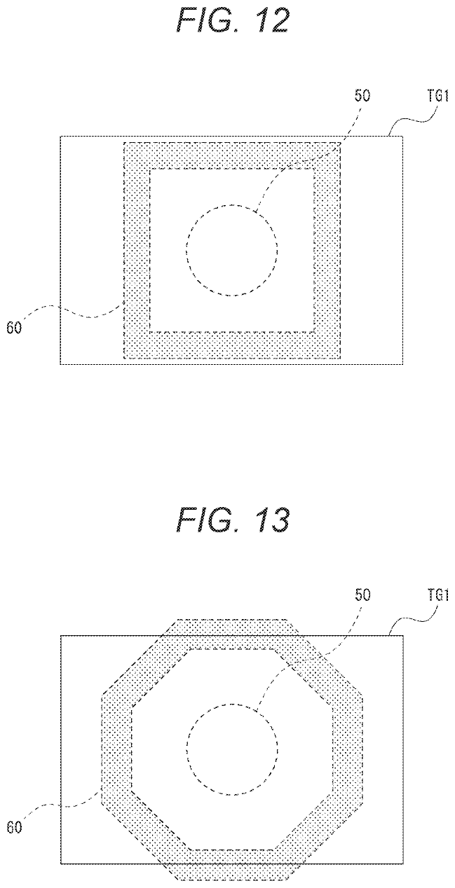

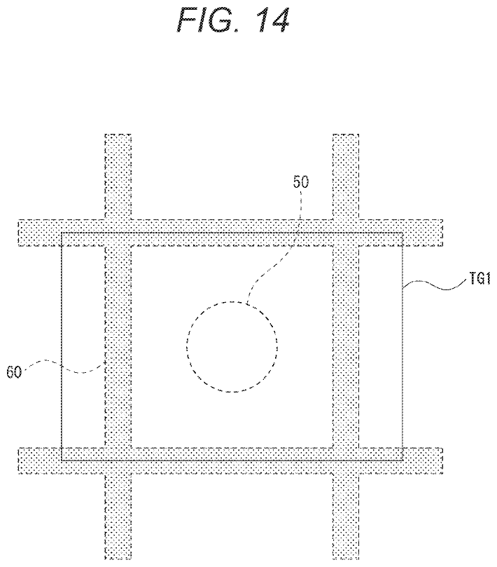

In addition, in the above description, the example has been described in which the shield part 60 has an annular shape. However, regarding the shape of the shield part 60, specifically, the cross-sectional shape in the in-plane direction, other shapes such as a quadrangular shape exemplified in FIG. 12, a polygonal shape exemplified in FIG. 13, and a parallel cross beam shape exemplified in FIG. 14 can be adopted.

Among these examples, in a case where the shield part has a quadrangular shape or a parallel cross beam shape, gas used in the dry etching tends to easily enter a corner part or an intersection portion at the time of forming a trench, and the trench can be dug deeply at the corner part or the intersection portion. The shield effect (the effect of reducing the capacitive load from other wiring lines) can be enhanced at the portion dug deeply, and the effect of reducing the wiring capacitance Cw can be enhanced.

Here, in a case where the shield part 60 has an annular shape as in the example in FIG. 6 described above, there is an advantage that the depth of the shield part 60 can be easily made uniform in a case where the shield part 60 is formed by digging a trench into the wiring layer part 32.

Note that not only the shield part 60 but also the shield parts 60B and 60C are similar in terms of not being limited to the annular shape.

Furthermore, in the above description, the configuration in which the charges of the photodiode PD are transferred to the floating diffusion FD via the transfer transistor TG has been exemplified. However, for example, as a configuration corresponding to global reading, a configuration in which the charges of the photodiode PD are transferred to a memory element via the transfer transistor TG, and then the charges accumulated in the memory element are transferred to the floating diffusion FD via a separate transfer transistor can be adopted. Note that, in this case, the memory element described above can be said to be a charge holding part that holds the charges accumulated in the photoelectric conversion element.

Furthermore, in the above description, the example has been described in which the sensor unit 1 performs sensing for distance measurement by the indirect ToF method. However, the present technology can be widely and suitably applied to a sensor device including a pixel including a photoelectric conversion element that performs photoelectric conversion, a first charge holding part and a second charge holding part that hold charges accumulated in the photoelectric conversion element, a first transfer transistor that transfers the charges to the first charge holding part, and a second transfer transistor that transfers the charges to the second charge holding part.

### 4. Summary of Embodiments

As described above, the sensor device (the sensor unit 1) as the embodiment includes: the semiconductor substrate (the semiconductor substrate 31); and the wiring layer part (the wiring layer part 32) disposed on the semiconductor substrate and having the plurality of wiring layers, in which: the semiconductor substrate and the wiring layer part constitute a laminated structure in which the pixel (the pixel Px, PxA, PxB, or PxC) is disposed, the pixel including the photoelectric conversion element (the photodiode PD) that performs photoelectric conversion, the first charge holding part and the second charge holding part (for example, the floating diffusions FD1 and FD2) that hold charges accumulated in the photoelectric conversion element, the first transfer transistor (for example, the transfer transistor TG1) that transfers the charges to the first charge holding part, and the second transfer transistor (for example, the transfer transistor TG2) that transfers the charges to the second charge holding part; and the first transfer transistor and the second transfer transistor extending in the thickness direction in the wiring layer part each include the gate wiring line (the gate wiring line 50 or 50A) that has the shield part (the shield part 60, 60B, or 60C) surrounding the gate wiring line.

The shield part can reduce the capacitive load on the gate wiring line from the peripheral wiring lines.

Therefore, the wiring capacitance of the gate wiring line can be reduced, and the power consumption of the sensor device can be reduced.

Furthermore, in the sensor device as the embodiment, the shield part is disposed across the plurality of wiring layers.

With this arrangement, a range in which the shield part covers the gate wiring line in the laminating direction of the wiring layer part becomes wider.

Therefore, the effect of reducing the wiring capacitance of the gate wiring line can be enhanced.

Moreover, in the sensor device as the embodiment, the gate wiring line (the gate wiring line 50) includes a wiring line extending in the in-plane direction on the inner side of the shield part.

With this arrangement, at the time of forming the gate wiring line in the region on the inner side of the shield part, the same process as the forming process of the wiring line in the outer region of the shield part can be applied, the process including the forming of the wiring line (to be dummy) in each wiring layer part before the forming of a via for one layer.

Therefore, the manufacturing efficiency of the sensor device can be improved in reducing the wiring capacitance of the gate wiring line.

Still further, in the sensor device as the embodiment, the gate wiring line (the gate wiring line 50A) includes the through via penetrating the plurality of wiring layers.

By forming the through via, the wiring line does not need to be formed in the in-plane direction in the gate wiring line, which enables the gate wiring line to be made thin.

Therefore, the effect of reducing the wiring capacitance of the gate wiring line can be enhanced.

Furthermore, in the sensor device as the embodiment, the wiring layer part includes the inter-pixel wiring line (the gate drive line 21) being the connection destination of the gate wiring line in the farthest wiring layer (for example, the fourth wiring layer part 32a-4) which is the wiring layer farthest from the semiconductor substrate in the wiring layer part, and the shield part extends from the adjacent wiring layer (for example, the third wiring layer 32a-3) of the farthest wiring layer in the wiring layer part toward the side of the semiconductor substrate.

With this arrangement, in a case where the shield part is formed by digging the trench into the wiring layer part, the range in which the shield part covers the gate wiring line in the laminating direction of the wiring layer part can be maximized.

Therefore, the effect of reducing the wiring capacitance of the gate wiring line can be enhanced.

Moreover, in the sensor device as the embodiment, the shield part has an annular cross-sectional shape in the in-plane direction (see FIG. 6).

With this arrangement, in a case where the shield part is formed by digging the trench into the wiring layer part, the depth of the shield part can be easily made uniform.

Therefore, the accuracy of forming the shield part can be enhanced.

Still further, in the sensor device as the embodiment, the shield part includes the insulating material that is different from the interlayer insulating material in the wiring layer part.

With this arrangement, the shield part can include a material having higher insulating properties than the interlayer insulating material.

Therefore, the effect of reducing the wiring capacitance of the gate wiring line can be enhanced, and the power consumption of the sensor device can be further reduced.

Furthermore, in the sensor device as the embodiment, the shield part includes the Low-k material.

With this arrangement, the insulating properties of the shield part is enhanced.

Therefore, the effect of reducing the wiring capacitance of the gate wiring line can be enhanced, and the power consumption of the sensor device can be further reduced.

Moreover, in the sensor device as the embodiment, the shield part (the shield part 60B) includes the cavity part (see FIG. 10).

With this arrangement, in a case where the shield part is formed by digging the trench into the wiring layer part, a process of filling the trench with the insulating material becomes unnecessary.

Therefore, the manufacturing efficiency of the sensor device can be improved in reducing the wiring capacitance of the gate wiring line.

Still further, the sensor device as the embodiment includes a sensor device for distance measurement using the indirect ToF method.

In the indirect ToF, because the first and second transfer transistors are driven at high speed, the power consumption tends to increase.

Therefore, the technology as the embodiment is preferably applied.

Furthermore, the sensing module (the sensing module 6) as the embodiment includes: the light-emitting unit (the light-emitting unit 2) that emits light for distance measurement; and the sensor unit (the sensor unit 1) that receives the light emitted from the light-emitting unit and reflected by the object, in which: the sensor unit includes the semiconductor substrate (the semiconductor substrate 31), and the wiring layer part (the wiring layer part 32) disposed on the semiconductor substrate and having the plurality of wiring layers; the semiconductor substrate and the wiring layer part constitute a laminated structure in which the pixel (the pixel Px, PxA, PxB, or PxC) is disposed, the pixel including the photoelectric conversion element (the photodiode PD) that performs photoelectric conversion, the first charge holding part and the second charge holding part (for example, the floating diffusions FD1 and FD2) that hold charges accumulated in the photoelectric conversion element, the first transfer transistor (for example, the transfer transistor TG1) that transfers the charges to the first charge holding part, and the second transfer transistor (for example, the transfer transistor TG2) that transfers the charges to the second charge holding part; and the first transfer transistor and the second transfer transistor extending in the thickness direction in the wiring layer part each include the gate wiring line (the gate wiring line 50 or 50A) that has the shield part (the shield part 60, 60B, or 60C) surrounding the gate wiring line.

Also with a sensing module as such an embodiment, an action similar to that of the sensor device according to the embodiment described above can be obtained.

Note that the effects described in the present description are merely examples and are not limited, and other effects may be provided.

### 5. Present Technology

Note that the present technology can also take the following configurations.

(1)

A sensor device including:
a semiconductor substrate; and a wiring layer part disposed on the semiconductor substrate and having a plurality of wiring layers, in which:
the semiconductor substrate and the wiring layer part constitute a laminated structure in which a pixel is disposed, the pixel including
a photoelectric conversion element that performs photoelectric conversion,
a first charge holding part and a second charge holding part that hold charges accumulated in the photoelectric conversion element,
a first transfer transistor that transfers the charges to the first charge holding part, and
a second transfer transistor that transfers the charges to the second charge holding part; and
a shield part surrounding a gate wiring line is formed for the gate wiring line of each of the first transfer transistor and the second transfer transistor extending in a thickness direction in the wiring layer part.

(2)

The sensor device according to (1), in which the shield part is disposed across a plurality of the wiring layers.

(3)

The sensor device according to (1) or (2), in which the gate wiring line includes a wiring line extending in an in-plane direction on an inner side of the shield part.

(4)

The sensor device according to any one of (1) to (3), in which the gate wiring line includes a through via penetrating the plurality of the wiring layers.

(5)

The sensor device according to any one of (1) to (4), in which
an inter-pixel wiring line being a connection destination of the gate wiring line is formed in a farthest wiring layer which is the wiring layer farthest from the semiconductor substrate in the wiring layer part, and
the shield part extends from an adjacent wiring layer of the farthest wiring layer in the wiring layer part toward a side of the semiconductor substrate.

(6)

The sensor device according to any one of (1) to (5), in which the shield part has an annular cross-sectional shape in the in-plane direction.

(7)

The sensor device according to any one of (1) to (6), in which the shield part includes an insulating material that is different from an interlayer insulating material in the wiring layer part.

(8)

The sensor device according to (7), in which the shield part includes a Low-k material.

(9)

The sensor device according to any one of (1) to (6), in which the shield part is formed as a cavity part.

(10)

The sensor device according to any one of (1) to (9), in which the sensor device is formed as a sensor device for distance measurement using an indirect ToF method.

(11)

A sensing module including:
a light-emitting unit that emits light for distance measurement; and
a sensor unit that receives the light emitted from the light-emitting unit and reflected by an object, in which:
the sensor unit includes a semiconductor substrate and a wiring layer part disposed on the semiconductor substrate and having a plurality of wiring layers;
the semiconductor substrate and the wiring layer part constitute a laminated structure in which a pixel is disposed, the pixel including
a photoelectric conversion element that performs photoelectric conversion,
a first charge holding part and a second charge holding part that hold charges accumulated in the photoelectric conversion element,
a first transfer transistor that transfers the charges to the first charge holding part, and
a second transfer transistor that transfers the charges to the second charge holding part; and
a shield part surrounding a gate wiring line is formed for the gate wiring line of each of the first transfer transistor and the second transfer transistor extending in a thickness direction in the wiring layer part.

### REFERENCE SIGNS LIST

1 Sensor unit (Sensor device)
2 Light-emitting unit
6 Sensing module
10 Distance measuring device
Ob Object
Li Irradiation light
Lr Reflected light
11 Pixel array unit
12 Transfer gate drive unit
21, 21-1, 21-2 Gate drive line
22, 22-1, 22-2 Vertical signal line
Px, PxA, PxB, PxC Pixel
PD Photodiode
FD, FD1, FD2 Floating diffusion
TG, TG1, TG2 Transfer transistor
STG, STG1, STG2 Transfer drive signal
Ss Front surface
Sb Back surface
31 Semiconductor substrate
32 Wiring layer part
32a Wiring layer
32a-1 First wiring layer
32a-2 Second wiring layer
32a-3 Third wiring layer
32a-4 Fourth wiring layer
32b Interlayer insulating film
34 Boundary part (Pixel boundary part)
50, 50A Gate wiring line
60, 60B, 60C Shield part

What is claimed is:

1. A sensor device, comprising:
a semiconductor substrate; and
a wiring layer part disposed on the semiconductor substrate and having a plurality of wiring layers,
wherein:
the semiconductor substrate and the wiring layer part constitute a laminated structure in which a pixel is disposed, the pixel including:
a photoelectric conversion element that performs photoelectric conversion;
a first charge holding part and a second charge holding part that hold charges accumulated in the photoelectric conversion element;
a first transfer transistor that transfers the charges to the first charge holding part; and
a second transfer transistor that transfers the charges to the second charge holding part; and
a shield part surrounding a gate wiring line is formed for the gate wiring line of each of the first transfer transistor and the second transfer transistor extending in a thickness direction in the wiring layer part.

2. The sensor device according to claim 1, wherein the shield part is disposed across a plurality of the wiring layers.

3. The sensor device according to claim 1, wherein the gate wiring line includes a wiring line extending in an in-plane direction on an inner side of the shield part.

4. The sensor device according to claim 1, wherein the gate wiring line includes a through via penetrating the plurality of the wiring layers.

5. The sensor device according to claim 1, wherein
an inter-pixel wiring line being a connection destination of the gate wiring line is formed in a farthest wiring layer which is the wiring layer farthest from the semiconductor substrate in the wiring layer part, and
the shield part extends from an adjacent wiring layer of the farthest wiring layer in the wiring layer part toward a side of the semiconductor substrate.

6. The sensor device according to claim 1, wherein the shield part has an annular cross-sectional shape in an in-plane direction.

7. The sensor device according to claim 1, wherein the shield part includes an insulating material that is different from an interlayer insulating material in the wiring layer part.

8. The sensor device according to claim 7, wherein the shield part includes a Low-k material.

9. The sensor device according to claim 1, wherein the shield part is formed as a cavity part.

10. The sensor device according to claim 1, wherein the sensor device is formed as a sensor device for distance measurement using an indirect ToF method.

11. A sensing module, comprising:
a light-emitting unit that emits light for distance measurement; and
a sensor unit that receives the light emitted from the light-emitting unit and reflected by an object,
wherein:
the sensor unit includes a semiconductor substrate and a wiring layer part disposed on the semiconductor substrate and having a plurality of wiring layers;
the semiconductor substrate and the wiring layer part constitute a laminated structure in which a pixel is disposed, the pixel including:
a photoelectric conversion element that performs photoelectric conversion;
a first charge holding part and a second charge holding part that hold charges accumulated in the photoelectric conversion element;
a first transfer transistor that transfers the charges to the first charge holding part; and
a second transfer transistor that transfers the charges to the second charge holding part; and
a shield part surrounding a gate wiring line is formed for the gate wiring line of each of the first transfer transistor and the second transfer transistor extending in a thickness direction in the wiring layer part.
